(19) United States
(12) Patent Application Publication
(10) Pub. No.: US 2026/0117360 A1
(43) Pub. Date: Apr. 30, 2026

(54) DEPOSITION MASK FOR OLED PIXEL DEPOSITION

(71) Applicant: LG INNOTEK CO., LTD., Seoul (KR)

(72) Inventors: Su Hyeon CHO, Seoul (KR); Dong Mug SEONG, Seoul (KR); Sang Yu LEE, Seoul (KR)

(21) Appl. No.: 19/117,124

(22) PCT Filed: Aug. 31, 2023
(86) PCT No.: PCT/KR2023/012992

§ 371 Date: Mar. 31, 2025

(30) Foreign Application Priority Data
Sep. 30, 2022 (KR) 10-2022-0125310

(51) Int. Cl. C23C 14/04; H10K 71/16

(52) U.S. Cl. CPC C23C 14/042; H10K 71/166

(57) ABSTRACT

A deposition mask comprising; a metal plate including a deposition region and a non-deposition region, wherein the metal plate has a first direction, which is a longitudinal direction, and a second direction, which is a width direction, defined, wherein the metal plate includes a first surface and a second surface opposite to the first surface, wherein the deposition region includes a plurality of effective regions; and a non-effective region, wherein the non-effective region includes a first non-effective region between a plurality of effective regions; and a second non-effective region between the effective region and both ends of the metal plate in a second direction, wherein a first through-hole is formed in the effective region, wherein a second through-hole is formed in the first non-effective region, wherein a third through-hole is formed in the second non-effective region.

### TECHNICAL FIELD

An embodiment relates to a deposition mask for OLED pixel deposition.

### BACKGROUND ART

Display devices are applied to various devices. For example, the display device is applied to a small device such as a smart phone or a tablet PC. Alternatively, the display device is applied to a large-sized device such as a TV, monitor, or public display. Recently, the demand for ultra-high definition (UHD) of 500 pixels per inch (PPI) or more is increasing. Accordingly, display devices having high resolution are being applied to small devices and large devices.

Display devices are classified into liquid crystal display (LCD) and organic light emitting diode (OLED) according to driving methods.

The LCD is a display device driven using liquid crystal. In addition, OLED is a display device driven by using an organic material.

The OLED can express an infinite contrast ratio, has a response speed that is 1000 times faster than LCD, and has an excellent viewing angle. Accordingly, the OELD is attracting attention as a display device that can replace the LCD.

The OLED includes a light emitting layer. The light emitting layer includes an organic material. The organic material is deposited on the substrate using a deposition mask. The deposition mask may include an open mask (OM) or a fine metal mask (FMM). A deposition pattern corresponding to a pattern formed on a deposition mask is formed on the substrate. Accordingly, the deposition pattern may serve as a pixel.

The open mask is a thin plate that forms a deposition pattern only at a specific location when manufacturing an OLED. The open mask is used in a deposition process of forming a light emitting layer thereon after a backplane is completed in a display manufacturing process. That is, the open mask is a mask that does not cover a portion within an operating range of the display in order to deposit the entire surface of the display. Therefore, the open mask is used when depositing a light emitting layer with a light emitting material of one color.

On the other hand, the fine metal mask is used to change the color of the sub-pixels of the light emitting layer. Accordingly, the fine metal mask includes ultra-fine holes. The process of using the fine metal mask requires a multi-step deposition process. Therefore, the process requires accurate alignment. Accordingly, the process using the fine metal mask is more difficult than the process using the open mask.

When the light emitting layer of the OLED is deposited using an open mask, only a single-color light emitting layer is formed. Therefore, separate color filters are required to implement various colors. On the other hand, when using the fine metal mask, an RGB light emitting layer may be formed. Therefore, a separate color filter is not required. That is, the technique using the fine metal mask has a high degree of difficulty. However, compared to the method using an open mask, light efficiency is good because a filter for blocking light is not required.

The fine metal mask is generally made of an Invar alloy metal plate including iron (Fe) and nickel (Ni). Through-holes are formed through one surface and the other surface of the metal plate. The through-hole is formed at a position corresponding to the pixel pattern. Accordingly, red, green, and blue organic materials may pass through the through-hole of the metal plate and be deposited on the deposition substrate. Accordingly, a pixel pattern may be formed on the deposition substrate.

Meanwhile, the fine metal mask includes a small surface hole formed on one surface of the metal plate and a large surface hole formed on the other surface of the metal plate. The small face hole and the large surface hole are connected by a connecting portion. As a result, the through-hole is formed.

The organic material is sprayed in the direction of the fine metal mask. The organic material is deposited on the deposition substrate using the large surface hole as an inlet and the small surface hole as an outlet.

In detail, strip-shaped fine metal masks are disposed on the deposition substrate. The organic material moves in the direction of the small surface hole through the large surface hole.

At this time, the fine metal masks are fixed to the frame. In detail, the fine metal mask is stretched in the longitudinal direction of the mask and fixed to the frame.

Depending on the difference in the area of the opening formed in the fine metal mask, a different amount of tensile force may be generated in each area. Accordingly, the shape of the fine metal mask may be deformed.

In addition, tensile stress is generated by the tension. Accordingly, waviness may occur on the surface of the fine metal mask.

The distance between the small surface hole and the large surface hole may be changed by the shape change and waviness. Accordingly, when the organic material is deposited using the fine metal mask, the deposition position of the organic material is changed. Accordingly, deposition reliability may be reduced.

Accordingly, a deposition mask having a new structure capable of solving the above problems is required.

### DISCLOSURE

### Technical Problem

An embodiment provides a deposition mask having improved deposition reliability.

### Technical Solution

A deposition mask comprising; a metal plate including a deposition region and a non-deposition region, wherein the metal plate has a first direction, which is a longitudinal direction, and a second direction, which is a width direction, defined, wherein the metal plate includes a first surface and a second surface opposite to the first surface, wherein the deposition region includes a plurality of effective regions; and a non-effective region, wherein the non-effective region includes a first non-effective region between a plurality of effective regions; and a second non-effective region between the effective region and both ends of the metal plate in a second direction, wherein a first through-hole is formed in the effective region, wherein a second through-hole is formed in the first non-effective region, wherein a third through-hole is formed in the second non-effective region.

### Advantageous Effects

A deposition mask according to an embodiment includes a through-hole formed in a deposition region. The deposition region includes an effective region and a non-effective region.

Accordingly, the opening area of the effective region becomes similar. Accordingly, when the deposition mask is stretched in the first direction, a similar tensile force is generated in the effective region. Accordingly, when the deposition mask is stretched in the first direction, a deformation difference between regions due to tension is reduced.

In addition, through-holes are additionally disposed in the non-effective region. The through-holes distribute residual stress of the deposition mask. In detail, the residual stress is generated by the tension. The residual stress is dispersed by the through-hole.

Accordingly, the stress distribution in the deposition region becomes uniform.

That is, a plurality of through-holes having the same or similar shape or size are formed in the effective region and the non-effective region. Therefore, when the deposition mask is stretched in the first direction, the residual stress is uniformly distributed. Accordingly, waviness of the deposition mask is reduced.

Also, the deposition mask includes an alignment region and a pattern. The alignment region is disposed in the non-effective region. The pattern is disposed in the alignment region.

The position of the effective region is set by the alignment region. Therefore, even if through-holes are formed in all of the deposition regions, the positions of the effective regions can be easily identified.

In addition, intervals between the effective regions are made uniform by the alignment region. Accordingly, intervals between the deposition patterns become uniform.

Also, the shape or size of the through-hole disposed in the effective region and the through-hole disposed in the non-effective region may be different.

Accordingly, the position of the effective region may be set by a difference in shape or size of the through-hole. Therefore, even when through-holes are formed in all of the deposition regions, the positions of the effective regions are easily identified.

In addition, a process of forming a separate alignment region may be omitted. Thus, process efficiency is improved. Also, the stress in the non-effective region is effectively dispersed.

In addition, the deposition mask includes a fourth island portion disposed in the second non-effective region.

An area of the fourth island portion is greater than areas of the first island portion, the second island portion, and the third island portion.

Accordingly, the position of the effective region may be set by the fourth island portion. Therefore, even when through-holes are formed in all of the deposition regions, the positions of the effective regions are easily identified.

In addition, intervals between the effective regions are made uniform by the fourth island portion. Accordingly, the intervals between the deposition patterns become uniform.

In addition, the deposition mask includes a fifth island portion disposed in the first non-effective region.

An area of the fifth island portion is larger than areas of the first island portion, the second island portion, and the third island portion.

Accordingly, intervals between the effective regions are aligned by the fifth island portion. Accordingly, the intervals between the deposition patterns becomes uniform.

### DESCRIPTION OF DRAWINGS

FIG. 1 is a view showing a combination of a deposition mask and a frame according to an embodiment.

FIG. 2 is a cross-sectional view of an organic material deposition apparatus including the deposition mask according to the embodiment.

FIG. 3 is a view illustrating formation of a deposition pattern on a deposition substrate by through-holes of the deposition mask according to the embodiment.

FIG. 4 is a plan view of the deposition mask according to a first embodiment.

FIG. 5 is a cross-sectional view taken along a region A-A′ of FIG. 4.

FIG. 6 is a cross-sectional view taken along a region B-B′ of FIG. 4.

FIG. 7 is a cross-sectional view taken along a region C-C′ of FIG. 4.

FIG. 8 is a plan view of the deposition mask according to a second embodiment.

FIGS. 9a and 9b are enlarged views of region D of FIG. 8.

FIG. 10 is a cross-sectional view taken along a region E-E′ of FIG. 9.

FIG. 11 is a plan view of the deposition mask according to a third embodiment.

FIG. 12 is a cross-sectional view taken along a region F-F′ of FIG. 11.

FIG. 13 is a cross-sectional view taken along a region G-G′ of FIG. 11.

FIG. 14 is a plan view of the deposition mask according to a fourth embodiment.

FIG. 15 is an enlarged view of region H of FIG. 14.

FIG. 16 is a cross-sectional view taken along a region I-l′ of FIG. 14.

FIG. 17 is a cross-sectional view taken along a region J-J′ of FIG. 14.

FIG. 18 is a cross-sectional view taken along a region K-K′ of FIG. 15.

FIG. 19 is a cross-sectional view taken along a region L-L′ of FIG. 14.

FIG. 20 is a plan view of the deposition mask according to a fifth embodiment.

FIG. 21 is an enlarged view of region M of FIG. 20.

FIG. 22 is a cross-sectional view taken along a region N-N′ of FIG. 20

### MODES OF THE INVENTION

Hereinafter, embodiments of the present disclosure will be described in detail with reference to the accompanying drawings. However, the spirit and scope of the present disclosure is not limited to a part of the embodiments described, and may be implemented in various other forms, and within the spirit and scope of the present disclosure, one or more of the elements of the embodiments may be selectively combined and replaced. In addition, unless expressly otherwise defined and described, the terms used in the embodiments of the present disclosure (including technical and scientific terms) may be construed the same meaning as commonly understood by one of ordinary skill in the art to which the present disclosure belongs, and the terms such as those defined in commonly used dictionaries may be interpreted as having a meaning that is consistent with their meaning in the context of the relevant art.

In addition, the terms used in the embodiments of the present disclosure are for describing the embodiments and are not intended to limit the present disclosure. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present disclosure, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “connected” to another element, it may include not only when the element is directly “connected” to, “coupled” to, or “connected” to other elements, but also when the element is “connected”, “coupled”, or “connected” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements.

Furthermore, when expressed as “on (over)” or “under (below)”, it may include not only the upper direction but also the lower direction based on one element.

The deposition mask described below is a fine metal mask capable of forming an RGB pixel pattern on the deposition substrate by depositing red, green, and blue organic materials on the deposition substrate. In addition, the following description does not apply to the open mask.

In addition, the first direction 1D is defined as the longitudinal direction of the deposition mask. The second direction 2D is defined as the width direction of the deposition mask.

Hereinafter, a deposition mask according to an embodiment will be described with reference to the drawings.

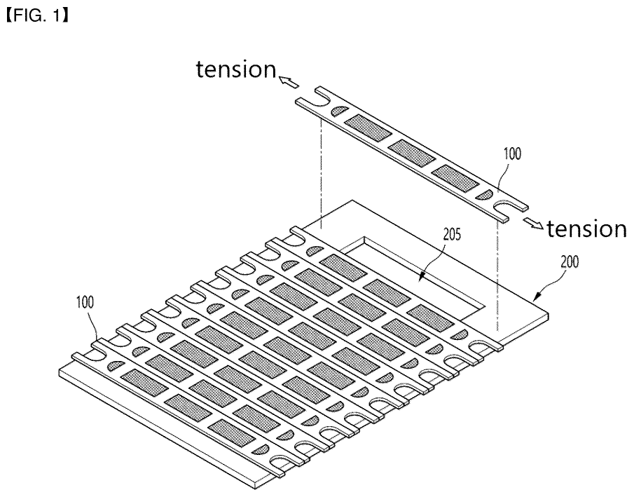

FIGS. 1 to 3 are views for explaining a process of depositing an organic material on a deposition substrate 300 using a deposition mask 100 according to an embodiment.

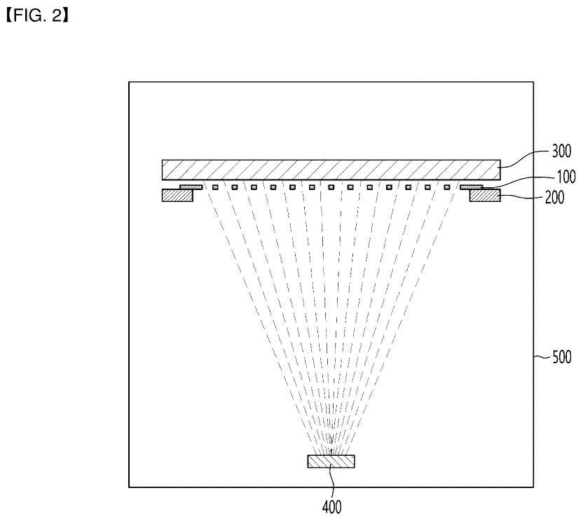

Referring to FIGS. 1 and 2, the organic material deposition apparatus includes a deposition mask 100, a mask frame 200, a deposition substrate 300, an organic material deposition container 400 and a vacuum chamber 500.

The deposition mask 100 includes metal. For example, the deposition mask includes iron (Fe) and nickel (Ni). In detail, the deposition mask includes an invar alloy including iron (Fe) and nickel (Ni).

The deposition mask 100 includes a plurality of through-holes TH. The through-hole is disposed in the effective portion. The through-hole is disposed to correspond to a pixel pattern to be formed on the deposition substrate.

The mask frame 200 includes an opening 205. The plurality of through-holes are disposed on a region corresponding to the opening 205. Accordingly, the organic material supplied to the organic material deposition container 400 is deposited on the deposition substrate 300. The deposition mask 100 is disposed and fixed on the mask frame 200. For example, the deposition mask 100 is tensioned with a set tensile force. In addition, the deposition mask 100 is welded and fixed on the mask frame 200.

For example, the non-effective portion of the deposition mask 100 is welded. Accordingly, the deposition mask 100 is fixed on the mask frame 200. Then, the portion protruding out of the mask frame 200 is cut and removed.

The mask frame 200 includes metal having high rigidity. Thus, deformation of the mask frame during the welding process is reduced.

The deposition substrate 300 is a substrate used when manufacturing a display device. For example, an OLED pixel pattern is formed on the deposition substrate 300. Red, green, and blue organic patterns are formed on the deposition substrate 300 to form pixels that are three primary colors of light. That is, an RGB pattern is formed on the deposition substrate 300.

The organic material deposition container 400 is a crucible. The organic material is disposed inside the crucible. The organic material deposition container 400 moves inside the vacuum chamber 500. That is, the organic material deposition container 400 moves in one direction inside the vacuum chamber 500. For example, the organic material deposition container 400 moves in the width direction of the deposition mask 100 inside the vacuum chamber 500.

A heat source and/or current is supplied to the organic material deposition container 400. As a result, the organic material is deposited on the deposition substrate 300.

Referring to FIG. 3, the deposition mask 100 includes a metal plate 10. The metal plate includes a first surface 1S and a second surface 2S. The first surface 1S and the second surface 2S are opposite to each other.

The first surface 1S includes a small surface hole V1. The second surface 2S includes a large surface hole V2. For example, a plurality of small surface holes V1 and a plurality of large surface holes V2 are formed on the first surface 1S and the second surface 2S, respectively.

In addition, the deposition mask 100 includes a through-hole TH. The through-hole TH is formed by a connection portion CA connecting the boundary between the small surface hole V1 and the large surface hole V2.

The width of the large surface hole V2 is greater than that of the small surface hole V1. The width of the small surface hole V1 is measured on the first surface 1S of the deposition mask 100. The width of the large surface hole V2 is measured on the second surface 2S of the deposition mask 100.

Also, a width of the connection portion CA has a set size. In detail, the width of the connection portion CA may be 15 μm to 33 μm. In more detail, the width of the connection portion CA may be 19 μm to 33 μm. In more detail, the width of the connection portion CA may be 20 μm to 27 μm. When the width of the connection portion CA exceeds 33 μm, it is difficult to implement a resolution of 500 PPI or higher. In addition, when the width of the connection portion CA is less than 15 μm, defects may occur during the deposition process.

The small surface hole V1 faces the deposition substrate 300. The small surface hole V1 is disposed close to the deposition substrate 300. Accordingly, the small surface hole V1 has a shape corresponding to a deposition pattern DP.

The large surface hole V2 faces the organic material deposition container 400. Accordingly, the organic material supplied from the organic material deposition container 400 may be accommodated in a wide width by the large surface hole V2. In addition, a fine pattern may be rapidly formed on the deposition substrate 300 by the small surface hole V1.

Accordingly, the organic material accommodated by the large surface hole V2 is deposited on the deposition substrate 300 by the small surface hole V1. Accordingly, any one of red, green, and blue pixel patterns is formed on the deposition substrate 300. Then, the above process is repeated. Accordingly, red, green, and blue pixel patterns are all formed on the deposition substrate 300.

The deposition mask is stretched in one direction in order to be fixed to the mask frame. In detail, the deposition mask 100 is stretched in a first direction, which is a longitudinal direction.

At this time, the opening region of the deposition mask 100 is different for each region. Accordingly, the magnitude of the tensile force applied to each region may be different. Accordingly, the tensile length of the deposition mask 100 may vary for each region.

In addition, stress due to tension is formed inside the deposition mask 100. In addition, after the deposition mask 100 is fixed to the mask frame 200, residual stress is formed inside the deposition mask 100.

Accordingly, the stress in the region where the through-hole TH is formed and the stress in the region where the through-hole is not formed are distributed differently. Accordingly, the residual stress may be concentrated in a region where the through-hole is not formed. Accordingly, the surface of the deposition mask may be deformed. For example, the waviness of the surface may be increased.

Accordingly, an interval between the effective regions through which the organic material moves may vary. Alternatively, intervals of the through-holes may vary. Accordingly, when forming deposition patterns on the deposition substrate, intervals of the deposition patterns may be changed. As a result, the deposition reliability of the deposition mask is reduced.

Hereinafter, a deposition mask capable of solving the above problems will be described.

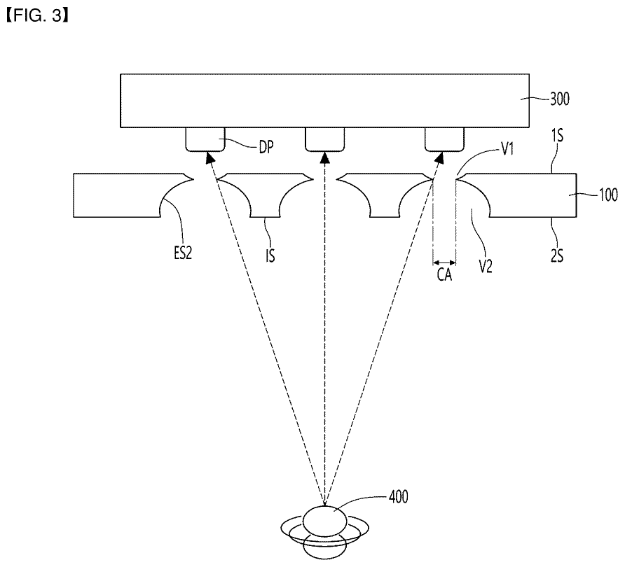

A deposition mask according to the first embodiment will be described with reference to FIGS. 4 to 7.

FIG. 4 is a plan view of the deposition mask 100 according to the first embodiment.

Referring to FIG. 4, the deposition mask 100 includes a deposition region DA and a non-deposition region NDA.

The deposition region DA is a region for forming a deposition pattern. The deposition region DA includes an effective region AA and a non-effective area UA. The effective region AA is a region through which the organic material passes. Also, the non-effective region UA is a region through which the organic material does not pass.

In the drawing, the effective region AA is shown in a rectangular shape. However, the embodiment is not limited thereto. The effective region AA may have a circular or elliptical shape including a curved surface.

The effective region AA includes a plurality of effective regions. The plurality of effective regions is spaced apart in the first direction.

The deposition region DA is a region from a point where the first through-hole TH starts to a point where the last through-hole TH ends in the first direction.

The non-effective region UA is a region other than the effective region AA in the deposition area DA. The non-effective region UA is divided into a first non-effective region UA1 and a second non-effective region UA2 according to positions.

The first non-effective region UA1 is a region between the effective region AA and a region between the non-deposited region NDA and the effective region AA. Accordingly, the plurality of first non-effective regions UA1 are spaced apart in the first direction 1D. In addition, the second non-effective region UA2 is a region between the effective area AA and both ends of the metal plate 10 in the second direction.

The non-deposition region NDA is a region not involved in deposition. The non-deposition region NDA includes a frame fixing region. The frame fixing region is a region where the deposition mask 100 is fixed to the mask frame 200. Also, the non-deposition region NDA includes an open portion OA. The open portion OA is formed by etching all of the metal plate 10. The open portion OA is a region to which a jig such as a clamp is fixed when the deposition mask 100 is tensioned.

Also, although not shown in the drawings, the non-deposition region NDA may further include a half etching portion. The half etching portion is formed by partially etching the metal plate 10.

The residual stress is dispersed by the half etching portion. Accordingly, the waviness of the non-deposition region is reduced.

Through-holes TH are formed in the effective region AA and the non-effective region UA, respectively. A first through-hole TH1 is disposed in the effective region AA. A second through-hole TH2 and a third through-hole TH3 are disposed in the non-effective region UA. For example, the second through-hole TH2 may be disposed in the first non-effective region UA1. In addition, the third through-hole TH3 may be disposed in the second non-effective region UA2.

The first through-hole TH1 and the second through-hole TH2 are formed in the same or similar shape. In addition, the first through-hole TH1 and the second through-hole TH2 are formed to have the same or similar sizes.

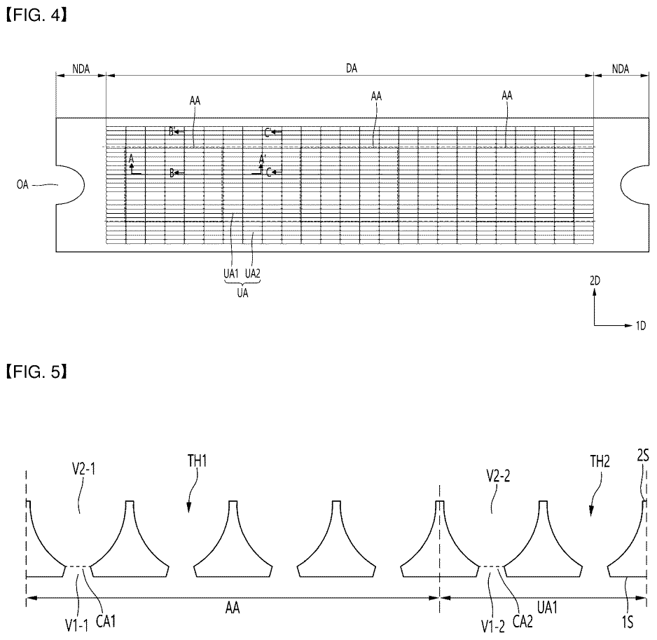

Referring to FIG. 5, the first through-hole TH1 includes a 1-1 small surface hole V1-1 and a 2-1 large surface hole V2-1 . The second through-hole TH2 includes a 1-2 small surface hole V1-2 and a 2-2 large surface hole V2-2 .

The first through-hole TH1 is formed by a first connecting portion CA1 connecting the 1-1 small surface hole V1-1 and the 2-1 large surface hole V2-1 . In addition, the second through-hole TH2 is formed by a second connection portion CA2 connecting the 1-2 small surface hole V1-2 and the 2-2 large surface hole V2-2 .

The 1-1 small surface hole V1-1 and the 1-2 small surface hole V1-2 may have the same or similar shapes. In addition, the size of the 1-1 small surface hole V1-1 and the 1-2 small surface hole V1-2 may be the same or similar. For example, the 1-1 small surface hole V1-1 and the 1-2 small surface hole V1-2 may have the same or similar widths. Alternatively, the heights of the 1-1 small surface hole V1-1 and the 1-2 small surface hole V1-2 may be the same or similar.

In addition, the shapes of the 2-1 large surface hole V2-1 and the 2-2 large surface hole V2-2 may be the same or similar. In addition, the size of the 2-1 large surface hole V2-1 and the 2-2 large surface hole V2-2 may be the same or similar. For example, the widths of the 2-1 large surface hole V2-1 and the 2-2 large surface hole V2-2 may be the same or similar. Alternatively, the heights of the 2-1 large surface hole V2-1 and the 2-2 large surface hole V1-2 may be the same or similar.

Also, the width of the first connection portion CA1 and the width of the second connection portion CA2 may be the same or similar.

The first through-hole TH1 and the third through-hole TH3 are formed in the same or similar shape. In addition, the first through-hole TH1 and the third through-hole TH3 are formed to have the same or similar sizes.

Referring to FIG. 6, the third through-hole TH3 includes a 1-3 small surface hole V1-3 and a 2-3 large surface hole V2-3. The third through-hole TH3 is formed by a third connection portion CA3 connecting the 1-3 small surface hole V1-3 and the 2-3 large surface hole V2-3.

The 1-1 small surface hole V1-1 and the 1-3 small surface hole V1-3 may have the same or similar shapes. In addition, the size of the 1-1 small surface hole V1-1 and the 1-3 small surface hole V1-3 may be the same or similar. For example, the 1-1 small surface hole V1-1 and the 1-3 small surface hole V1-3 may have the same or similar widths. Alternatively, the heights of the 1-1 small surface hole V1-1 and the 1-3 small surface hole V1-3 may be the same or similar.

In addition, the 2-1 large surface hole V2-1 and the 2-3 large surface hole V2-3 may have the same or similar shapes. In addition, the size of the 2-1 large surface hole V2-1 and the 2-3 large surface hole V2-3 may be the same or similar. For example, the 2-1 large surface hole V2-1 and the 2-3 large surface hole V2-3 may have the same or similar widths. Alternatively, the heights of the 2-1 large surface hole V2-1 and the 2-3 large surface hole V1-3 may be the same or similar.

Also, the width of the first connection portion CA1 and the width of the third connection portion CA3 may be the same or similar.

The second through-hole TH2 and the third through-hole TH3 are formed in the same or similar shape. The second through-hole TH2 and the third through-hole TH3 are formed to have the same or similar sizes.

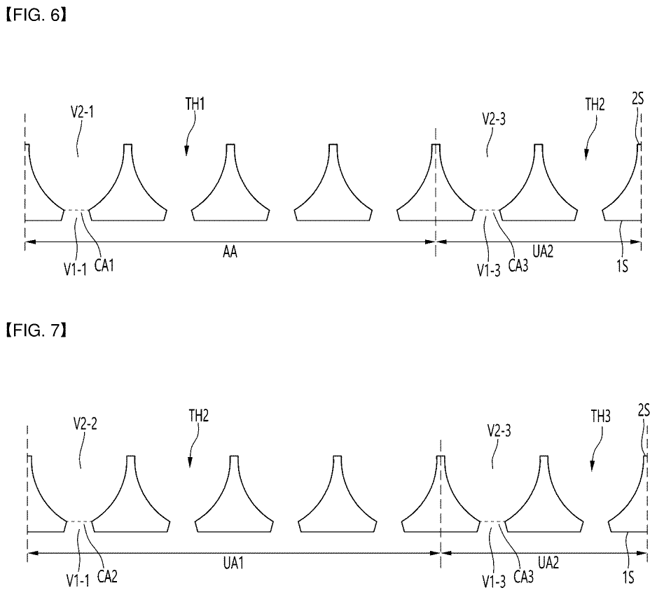

Referring to FIG. 7, the 1-2 small surface holes V1-2 and the 1-3 small surface holes V1-3 may have the same or similar shapes. In addition, the size of the 1-2 small surface hole V1-2 and the 1-3 small surface hole V1-3 may be the same or similar. For example, the 1-2 small surface hole V1-2 and the 1-3 small surface hole V1-3 may have the same or similar widths. Alternatively, the heights of the 1-2 small surface holes V1-2 and the 1-3 small surface holes V1-3 may be the same or similar.

In addition, the shapes of the 2-2 large surface hole V2-2 and the 2-3 large surface hole V2-3 may be the same or similar. In addition, the size of the 2-2 large surface hole V2-2 and the 2-3 large surface hole V2-3 may be the same or similar. For example, the 2-2 large surface hole V2-2 and the 2-3 large surface hole V2-3 may have the same or similar widths. Alternatively, the heights of the 2-2 large surface hole V2-2 and the 2-3 large surface hole V1-3 may be the same or similar.

Also, the width of the second connection portion CA2 and the width of the third connection portion CA3 may be the same or similar.

In addition, each of the first through-hole TH1, the second through-hole TH2, and the third through-hole TH3 is formed in plurality.

In detail, a plurality of first through-holes TH1 are formed in the effective region AA. Also, the plurality of first through-holes formed in the effective region AA have the same size. Also, the distances of adjacent first through-holes are the same.

In addition, a plurality of second through-holes TH2 are formed in the first non-effective region UA1. The plurality of second through-holes formed in the first non-effective region UA1 have the same size. Also, the distances of adjacent second through-holes may be the same.

In addition, a plurality of third through holes TH3 are formed in the second non-effective region UA2. The plurality of third through-holes formed in the second non-effective region UA2 have the same size. Also, the distances of adjacent third through-holes are the same.

In addition, a distance between the first through-hole TH1 and the second through-hole TH2 adjacent to each other in a region between the effective region AA and the first non-effective region UA1 may be the same as a distance between adjacent first through-holes TH1 in the effective region AA. In addition, a distance between the first through-hole TH1 and the third through-hole TH3 adjacent to each other in a region between the effective region AA and the second non-effective region UA2 may be the same as a distance between adjacent first through-holes TH1 in the effective region AA. In addition, a distance between the second through-hole TH2 and the third through-hole TH3 adjacent to each other in a region between the first non-effective region UA1 and the second non-effective region UA2 may be the same as a distance between adjacent first through-holes TH1 in the effective region AA.

A distance between the first through-hole TH1 and the second through-hole TH2 adjacent to each other in a region between the effective region AA and the first non-effective region UA1 may be the same as a distance between adjacent second through-holes TH2 in the first non-effective region UA1. In addition, a distance between the first through-hole TH1 and the third through-hole TH3 adjacent to each other in a region between the effective region AA and the second non-effective region UA2 may be the same as a distance between adjacent second through-holes TH2 in the first non-effective region UA1. In addition, a distance between the second through-hole TH2 and the third through-hole TH3 adjacent to each other in a region between the first non-effective region UA1 and the second non-effective region UA2 may be the same as a distance between adjacent second through-holes TH2 in the first non-effective region UA1.

A distance between the first through-hole TH1 and the second through-hole TH2 adjacent to each other in a region between the effective region AA and the first non-effective region UA1 may be the same as a distance between adjacent third through-holes TH3 in the second non-effective region UA2. In addition, a distance between the first through-hole TH1 and the third through-hole TH3 adjacent to each other in a region between the effective region AA and the second non-effective region UA2 may be the same as a distance between adjacent third through-holes TH3 in the second non-effective region UA2. In addition, a distance between the second through-hole TH2 and the third through-hole TH3 adjacent to each other in a region between the first non-effective region UA1 and the second non-effective region UA2 may be the same as a distance between adjacent third through-holes TH3 in the second non-effective region UA2.

The first island portion, the second island portion, and the third island portion formed in the effective region AA, the first non-effective region UA1, and the second non-effective region UA2 are formed in plurality. Areas of the first island portion, the second island portion, and the third island portion formed in the effective region AA, the first non-effective region UA1, and the second non-effective region UA2 may be the same.

In addition, the ratio of the region where the first through-hole TH1 is disposed to the total area of the effective area may be the same as the ratio of the region where the second through-hole TH2 is disposed to the total area of the first non-effective region.

Also, at least one of the plurality of first through-holes TH1, the plurality of second through-holes TH2, and the plurality of third through-holes TH3 may have the same size.

The first through-hole TH1, the second through-hole TH2, and the third through-hole TH3 are disposed at different positions. The first through-hole TH1 is disposed in the effective region AA. The first through-hole TH1 is a region through which the organic material passes. Accordingly, the deposition pattern is formed on the deposition substrate 300.

The second through-hole TH2 and the third through-hole TH3 are disposed in the non-effective region UA. The second through-hole TH2 and the third through-hole TH3 are regions through which the organic material does not pass. In detail, when the deposition pattern is formed on the deposition substrate 300, a mask is disposed on a region where the second through-hole TH2 and the third through-hole TH3 are disposed.

The opening area of the effective region becomes similar by the second through-hole TH2 and the third through-hole TH3. Accordingly, when the deposition mask is stretched in the first direction, a similar tensile force is applied to the effective region. Accordingly, when the deposition mask is stretched in the first direction, a deformation difference between regions due to tension is reduced.

In addition, the residual stress of the deposition mask is dispersed by the second through-hole TH2 and the third through-hole TH3. In detail, the residual stress generated by the tension is dispersed by the second through-hole TH2 and the third through-hole TH3.

Accordingly, in the deposition mask according to the first embodiment, the stress distribution in the deposition region becomes uniform.

That is, a plurality of through-holes having the same or similar shape or size are formed in the effective region and the non-effective region. Accordingly, residual stress remaining when the deposition mask is stretched in the first direction is uniformly distributed. Accordingly, waviness of the deposition mask is reduced.

The organic material may be deposited on the deposition substrate using a plurality of deposition masks. When the deposition mask is mounted on the mask frame, a positional error, a positional change of through-holes, and an alignment of the effective region may be misaligned. Through-holes disposed in the effective region and the non-effective region have the same size and interval. Accordingly, the organic material may be deposited even if the innermost through-hole of the non-effective region is aligned in the region where the outermost through-hole of the effective region is to be aligned.

Accordingly, it is possible to prevent deposition defects due to the error. In addition, even when the same deposition mask is reused, the deposition mask may be utilized. Alternatively, the deposition mask may be used even when deposition is performed on a deposition substrate having the same through-hole size but different deposition regions. In this case, when depositing on another deposition substrate having a large size, the first non-effective region and the second non-effective region may be used as a preliminary effective region. Alternatively, when deposition is performed on another deposition substrate having a small size, a part of the effective region may be used as a preliminary non-effective region. Accordingly, various displays may be manufactured using the same deposition mask. Therefore, manufacturing cost can be reduced.

A deposition mask according to a second embodiment will be described with reference to FIGS. 8 to 10. In the description of the deposition mask according to the second embodiment, the same or similar description as the deposition mask according to the first embodiment described above will be omitted.

Referring to FIG. 8, a plurality of through-holes are disposed in the deposition region DA. In detail, the effective region AA includes the first through-hole TH1. Also, the first non-effective region UA1 includes a second through-hole TH2. Also, the second non-effective region UA2 includes a third through-hole TH3.

The sizes or shapes of the first through-hole TH1, the second through-hole TH2, and the third through-hole TH3 may be the same as or similar to those of the first embodiment described above.

The second through-hole TH2 may be disposed at 70% or more, 80% or more, 90% or more, or 95% or more of the total area of the first non-effective region UA1.

Also, the area of the large surface holes formed on the second surface 2S may be 70% or more, 80% or more, 90% or more, or 95% or more of the total area of the deposition region DA.

In addition, except for the second island portion and the alignment region between the second through-holes described below, the area of the second through-hole region may be 100% of the total area of the first non-effective region UA1.

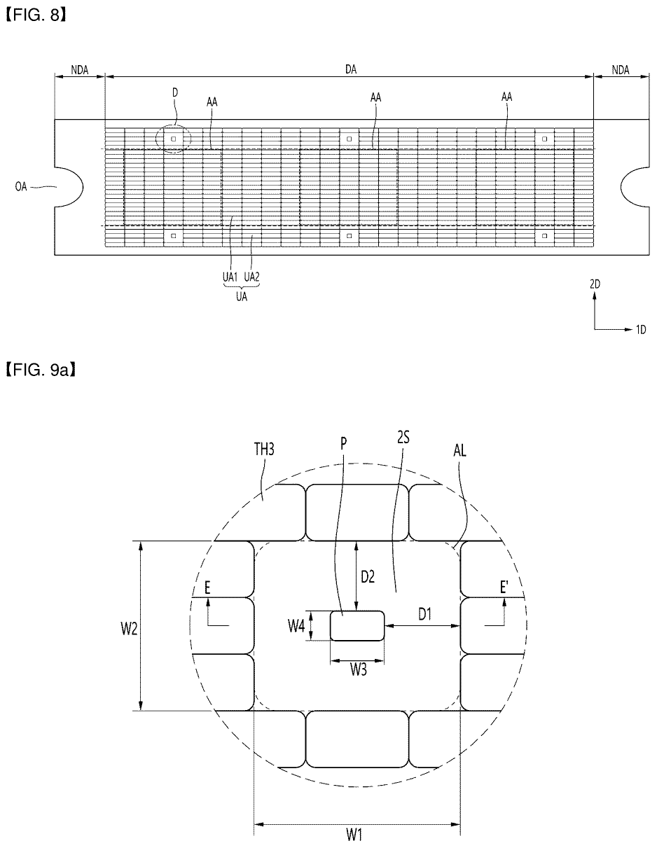

Referring to FIGS. 8 and 9, the deposition mask includes an alignment region AL. In detail, the alignment region AL is disposed on the second non-effective area UA2.

A plurality of alignment regions AL are disposed in the second non-effective region UA2. For example, one or more, two or more, or four or more alignment regions may be formed on each of the second non-effective regions UA2 corresponding to the effective region AA in the second direction.

The alignment region AL is spaced apart from each other in the first direction 1D and the second direction 2D. Also, the alignment region AL faces in the second direction 2D.

The alignment region AL is defined by the third through-hole TH3. In detail, the second non-effective region UA2 includes a region where the third through-hole TH3 is disposed and a region where the third through-hole TH3 is not disposed. The alignment region AL is the region in which the third through-hole is not disposed. Accordingly, the alignment region AL is a region where the metal plate 10 is not etched. That is, the alignment region AL is the second surface 2S.

An outer region of the alignment region AL is in contact with the third through-hole TH3. That is, the outer region of the alignment region AL is a region where the region in contact with the third through-hole TH3 extends.

The alignment region AL may include various shapes. For example, the alignment region AL may be formed in a shape having the same long width and short width. Alternatively, the alignment region AL may be formed in a shape having a long width and a short width different from each other.

A pattern P may be disposed inside the alignment region AL. In detail, at least one pattern P may be disposed inside the alignment region AL.

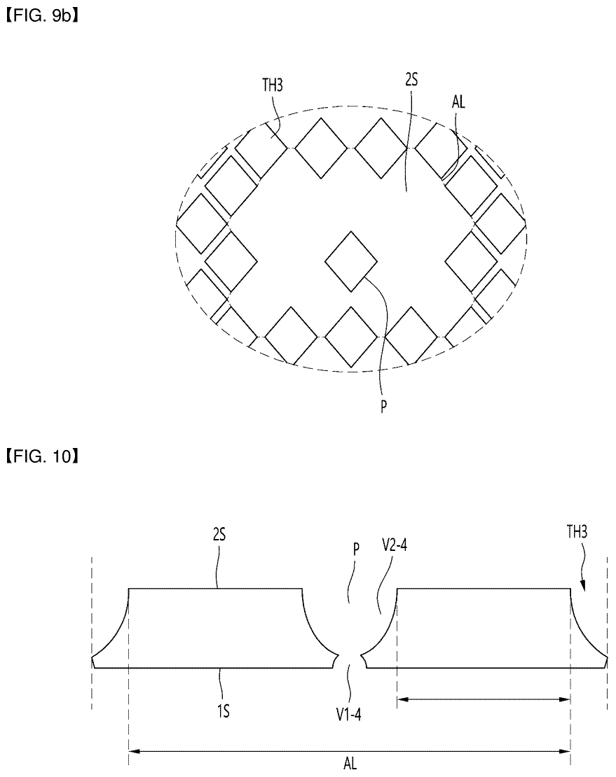

Referring to FIG. 10, the pattern P is formed by etching the metal plate 10. The pattern P is formed by etching the first surface 1S and the second surface 2S of the metal plate 10. The pattern (P) includes a small surface hole V1-4 and a large surface hole V2-4. The small surface holes V1-4 are formed by etching the first surface 1S. The large surface hole V2-4 is formed by etching the second surface 2S.

The size of the small surface holes V1-4 may be substantially the same the size of the small surface hole of at least one of the second through-hole and the third through-hole. Also, the size of the large surface hole V1-4 may be substantially the same as the size of the large surface hole of at least one of the second through-hole and the third through-hole.

Accordingly, when forming the second through-hole or the third through-hole, the pattern P may be formed together. Thus, process efficiency may be improved.

However, the embodiment is not limited thereto. The pattern P may be formed in a shape or size different from that of at least one of the second through-hole and the third through-hole. Also, in the drawings, one pattern P is disposed inside the alignment region AL. However, the embodiment is not limited thereto. A plurality of patterns P may be disposed inside the alignment region AL.

The pattern P aligns the position of the effective region AA. That is, the pattern P is an alignment mark. In the deposition mask, through-holes are formed even in non-effective regions. Therefore, the effective region and the non-effective region are not distinguished. Accordingly, the alignment region is formed in the non-effective region. Accordingly, the effective region and the non-effective region are distinguished.

Accordingly, when an organic material is deposited on the deposition substrate by the deposition mask, a region other than the effective region AA may be masked by the alignment region.

Also, the distance between the effective regions AA is made uniform by the alignment region. Accordingly, intervals of deposition patterns deposited on the deposition substrate become uniform.

The alignment region AL may have a set size. For example, the alignment region AL includes a first width W1 and a second width W2. The first width W1 is the width in the first direction. The second width W2 is a width in the second direction.

The first width W1 may be 5 mm or less. In detail, the first width W1 may be 1 mm to 5 mm, 1.2 mm to 3 mm, or 1.5 mm to 2 mm. Also, the second width W2 may be 5 mm or less. In detail, the second width W2 may be 1 mm to 5 mm, 1.2 mm to 3 mm, or 1.5 mm to 2 mm. The first width W1 and the second width W2 may be the same. Alternatively, the first width W1 and the second width W2 may be different.

When the first width W1 and the second width W2 exceed 5 mm, a region that is not etched may increase in the second non-effective region UA2. Accordingly, the force applied by the tensile force becomes non-uniform by the second non-effective region UA2. Accordingly, deformation may occur in the deposition mask. In addition, residual stress is concentrated in the alignment region. Accordingly, the waviness of the alignment region may increase. Accordingly, the position and interval of the alignment region change. As a result, since an interval of the deposition pattern is also changed, the deposition quality may be reduced.

Also, when the first width W1 and the second width W2 are less than 1 mm, the area of the alignment region AL becomes very small. Accordingly, when forming the pattern in the alignment region, the pattern may be formed outside the alignment region. Accordingly, defects may occur.

The pattern P and the outer region of the alignment region AL are spaced apart from each other. The pattern P is spaced apart from the alignment region AL by a first distance D1 and a second distance D2. The first distance D1 is a distance in a first direction. The second distance D2 is a distance in the second direction.

The first distance D1 and the second distance D2 may be the same. Alternatively, the first distance D1 and the second distance D2 may be different.

The pattern P may have a set size. For example, the pattern P has a third width W3 and a fourth width W4. The third width W3 is a width in the first direction. The fourth width W4 is a width in the second direction.

The third width W3 may be 70 μm or less. In detail, the third width W3 may be 20 μm to 70 μm, 30 μm to 60 μm, or 40 μm to 50 μm. Also, the fourth width W4 may be 70 μm or less. In detail, the fourth width W4 may be 20 μm to 70 μm, 30 μm to 60 μm, or 40 μm to 50 μm. The third width W3 and the fourth width W4 may be the same. Alternatively, the third width W3 and the fourth width W4 may be different.

The size of the pattern P is related to the size of the third through-hole TH3. The size of the pattern P may be the same as or similar to that of the large surface hole V2-3 of the third through-hole TH3.

In addition, the pattern P is formed in various shapes. For example, as shown in FIGS. 9A and 9B, the pattern P may be formed in an elliptical shape or a polygonal shape. Accordingly, the length direction of the pattern P may be the third width W3, and the width direction may be the fourth width W4. Alternatively, the width direction of the pattern P may be the third width W3, and the length direction of the pattern P may be the fourth width W4.

The deposition mask according to the second embodiment includes the alignment region disposed in the non-effective region and the pattern disposed inside the alignment region.

The alignment region sets the position of the effective region. Therefore, even when through-holes are formed in all of the deposition regions, the positions of the effective regions may be easily identified.

In addition, the interval between the effective regions is made uniform by the alignment region. Accordingly, the interval between the deposition patterns becomes uniform.

Hereinafter, a deposition mask according to a third embodiment will be described with reference to FIGS. 11 to 13. In the description of the deposition mask according to the third embodiment, the same or similar description as the deposition mask according to the first embodiment described above will be omitted.

The description of the deposition mask according to the third embodiment may be combined with the description of the deposition mask according to the first or second embodiment described above.

Referring to FIG. 11, a plurality of through-holes are disposed in the deposition region DA. The effective region AA includes a first through-hole TH1. The first non-effective region UA1 includes a second through-hole TH2. The second non-effective region UA2 includes a third through-hole TH3.

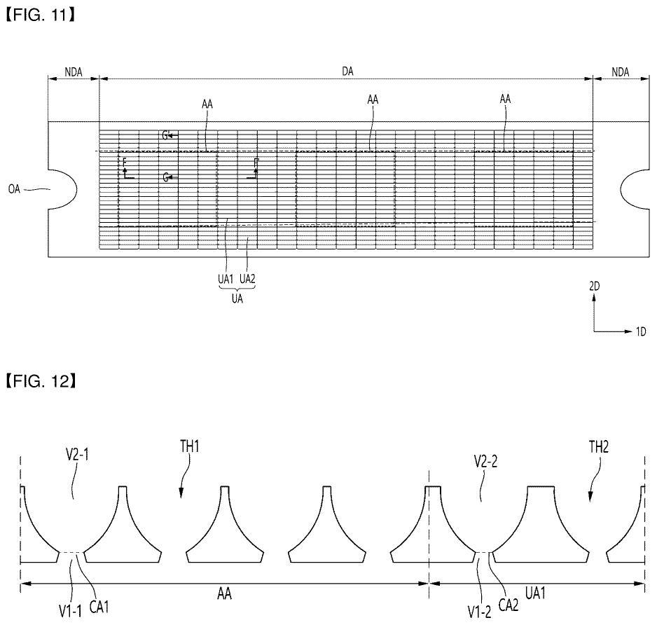

Referring to FIGS. 12 and 13, the deposition mask may have different sizes or shapes of the first through-hole TH1, the second through-hole TH2, and the third through-hole TH3.

Referring to FIG. 12, the first through-hole TH1 and the second through-hole TH2 may have different sizes or shapes.

For example, the width of the large surface hole V2-1 of the first through-hole TH1 may be different from the width of the large surface hole V2-2 of the second through-hole TH2.

For example, referring to FIG. 12, the width of the large surface hole V2-1 may be greater than that of the large surface hole V2-2 .

Alternatively, although not shown in the drawing, the width of the large surface hole V2-1 may be smaller than that of the large surface hole V2-2 . Alternatively, the height of the large surface hole V2-1 may be different from that of the large surface hole V2-2 . Alternatively, the width of the small surface hole V1-1 may be different from that of the small surface hole V1-2 . Alternatively, the height of the small surface hole V1-1 may be different from that of the small surface hole V1-2 . Alternatively, the width of the connecting portion CA1 of the first through-hole TH1 may be different from the width of the connecting portion CA2 of the second through-hole TH2.

Referring to FIG. 13, the first through-hole TH1 and the third through-hole TH3 may have different sizes or shapes.

For example, the width of the v hole V2-1 of the first through-hole TH1 may be different from the width of the large surface hole V2-3 of the third through-hole TH3.

For example, referring to FIG. 13, the width of the large surface hole V2-1 may be smaller than that of the large surface hole V2-3.

Alternatively, although not shown in the drawings, the width of the large surface hole V2-1 may be greater than that of the large surface hole V2-3. Alternatively, the height of the large surface hole V2-1 may be different from that of the large surface hole V2-3. Alternatively, the width of the small surface hole V1-1 may be different from that of the small surface hole V1-3. Alternatively, the height of the small surface hole V1-1 may be different from that of the small surface hole V1-3. Alternatively, the width of the connecting portion CA1 of the first through-hole TH1 may be different from the width of the connecting portion CA3 of the third through-hole TH3.

In the deposition mask according to the third embodiment, the shape or size of the through-hole disposed in the effective region and the through-hole disposed in the non-effective region are different from each other.

Accordingly, the position of the effective region may be set by a difference in shape or size of the through-hole. Therefore, even when through-holes are formed in all of the deposition regions, the positions of the effective regions may be easily identified.

In addition, a process of forming a separate alignment region may be omitted. Thus, process efficiency is improved. In addition, stress to the non-effective region is effectively dispersed.

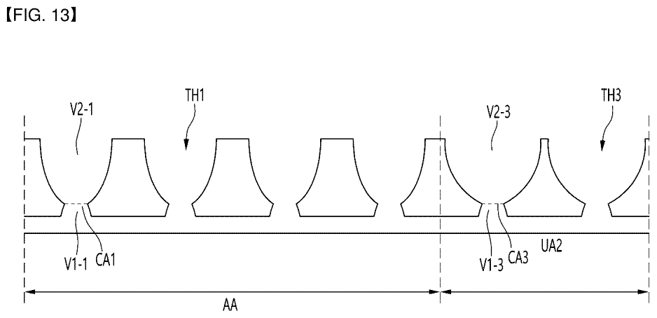

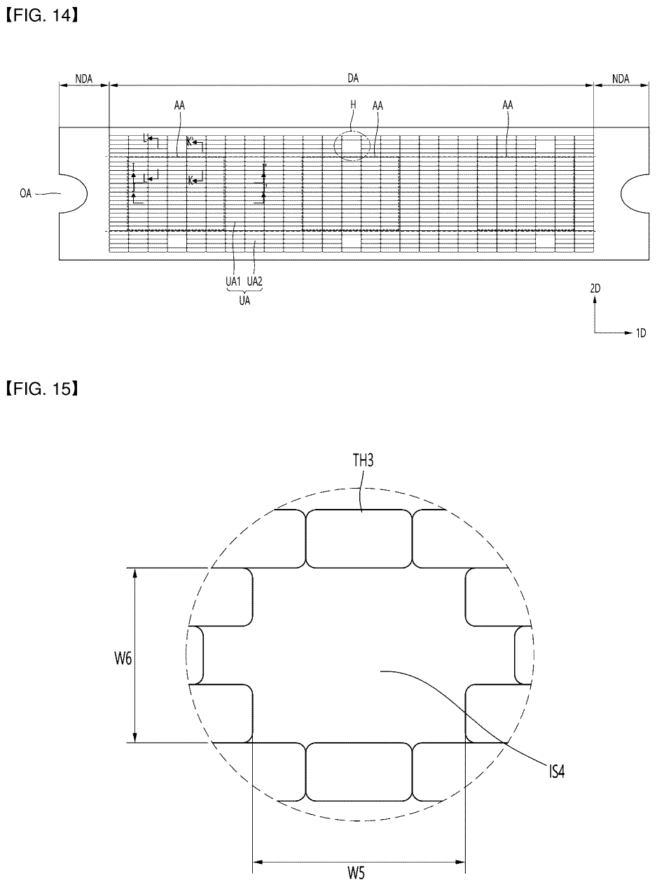

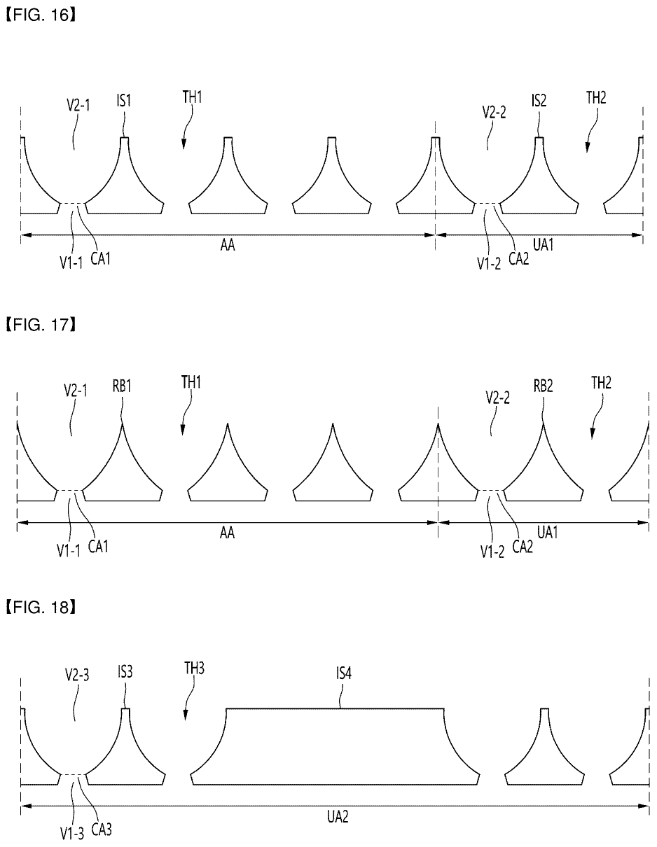

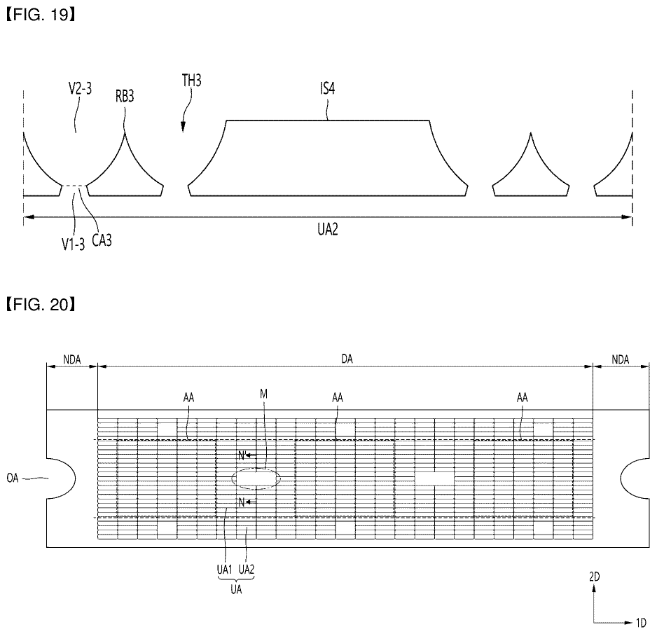

Hereinafter, a deposition mask according to a fourth embodiment will be described with reference to FIGS. 14 to 19. In the description of the deposition mask according to the fourth embodiment, the same or similar description as the deposition mask according to the first embodiment described above will be omitted.

Referring to FIG. 14, a plurality of through-holes are disposed in the deposition region DA. The effective region AA includes a first through-hole TH1. The first non-effective region UA1 includes a second through-hole TH2. The second non-effective region UA2 includes a third through-hole TH3.

The sizes or shapes of the first through-hole TH1, the second through-hole TH2, and the third through-hole TH3 may be the same as or similar to those of the first embodiment described above.

Referring to FIGS. 15 to 19, the deposition mask 100 includes an island portion and a rib.

The island portion is an unetched surface of the metal plate 10. In addition, the rib is a side region or a surface region where two surfaces meet when the metal plate 10 is partially etched. For example, the rib RB may be a side or a surface where the inner surfaces ES of the through-hole meet.

A first island portion IS1 and a first rib RB1 are formed in the effective region AA by the first through-hole TH1. In addition, a second island portion IS2 and a second rib RB2 are formed in the first non-effective region UA1 by the second through-hole TH2. In addition, a third island portion IS3, a fourth island portion IS4 and a third rib RB3 are formed in the second non-effective region UA2 by the third through-hole TH3.

Any one of the first island portion IS1, the second island portion IS2, the third island portion IS3, and the fourth island portion IS4 may differ in shape or size from other island portions.

In detail, the fourth island portion IS4 may have a different size or shape from the first island portion IS1, the second island portion IS2, and the third island portion IS3. For example, the first island portion IS1, the second island portion IS2, and the third island portion IS3 may have similar sizes or shapes. Also, the fourth island portion IS4 may have a different size or shape from the first island portion IS1, the second island portion IS2, and the third island portion IS3.

In detail, the shape of the fourth island portion IS4 is different from the shapes of the first island portion IS1, the second island portion IS2, and the third island portion IS3. Also, the area of the fourth island portion IS4 is larger than the areas of the first island portion IS1, the second island portion IS2, and the third island portion IS3.

A plurality of fourth island portions IS4 are disposed in the second non-effective region UA2. The fourth island portion IS4 is spaced apart from each other in the first direction 1D and the second direction 2D. Also, the fourth island portion IS4 faces in the second direction 2D.

The fourth island portion IS4 may have various shapes. For example, the fourth island portion IS4 may be formed in a shape having the same long width and short width. Alternatively, the fourth island portion IS4 may be formed in a shape having a long width and a short width different from each other.

The position of the effective region AA is aligned by the fourth island portion IS4. That is, the fourth island portion IS4 is an alignment mark. Accordingly, when an organic material is deposited on a deposition substrate by the deposition mask, a region other than the effective region AA may be masked by the fourth island portion IS4.

Also, the distance between the effective regions AA is made uniform by the fourth island portion IS4. Thus, the interval of the deposition patterns becomes uniform.

The fourth island portion IS4 has a set size. For example, the fourth island portion IS4 has a fifth width W5 and a sixth width W6. The fifth width W5 is a width in the first direction. The sixth width W6 is a width in the second direction.

The fifth width W5 may be 100 μm or less. In detail, the fifth width W5 may be 20 μm to 100 μm, 50 μm to 90 μm, or 60 μm to 80 μm. Also, the sixth width W6 may be 100 μm or less. In detail, the sixth width W6 may be 40 μm to 100 μm, 50 μm to 90 μm, or 60 μm to 80 μm. The fifth width W5 and the sixth width W6 may be the same. Alternatively, the fifth width W5 and the sixth width W6 may be different.

When the fifth width W5 and the sixth width W6 exceed 100 μm, a region that is not etched may increase in the second non-effective region UA2. Accordingly, the force applied by the tensile force becomes non-uniform by the second non-effective region UA2. Accordingly, deformation may occur in the deposition mask. Also, residual stress is concentrated in the fourth island portion. Accordingly, the waviness of the fourth island portion may be increased. Accordingly, the position and interval of the fourth island portion are changed. As a result, since the interval of the deposition pattern is also changed, the deposition quality is reduced.

Also, when the fifth width W5 and the sixth width W6 are less than 20 μm, the area of the fourth island portion becomes very small. Accordingly, a tolerance may increase when the effective region is aligned by the fourth island portion. As a result, since the tolerance of the interval of the deposition patterns is increased, deposition quality may be reduced.

Also, an area of the fourth island portion is larger than an area of a large surface hole of the first through-hole disposed in the effective region. For example, the area of the fourth island portion may be greater than or equal to 10 times the area of the large surface hole of the first through-hole disposed in the effective region and less than or equal to the area of the effective region. Alternatively, the area of the fourth island portion may be greater than or equal to 20 times the area of the large surface hole of the first through-hole disposed in the effective region and less than or equal to ½ of the area of the effective region. Alternatively, the area of the fourth island portion may be greater than or equal to 30 times the area of the large surface hole of the first through-hole disposed in the effective region and less than or equal to ⅓ of the area of the effective region. Alternatively, the area of the fourth island portion may be greater than or equal to 40 times the area of the large surface hole of the first through-hole disposed in the effective region and less than or equal to ¼ of the area of the effective region.

The deposition mask according to the fourth embodiment includes the fourth island portion disposed in the non-effective region.

The area of the fourth island portion is greater than areas of the first island portion, the second island portion, and the third island portion.

Accordingly, the position of the effective region disposed in the deposition region is set by the fourth island portion. Therefore, even when through-holes are formed in all of the deposition regions, the positions of the effective regions may be easily identified.

In addition, the interval between the effective regions is made uniform by the fourth island portion. Accordingly, the interval between the deposition patterns becomes uniform.

Hereinafter, a deposition mask according to a fifth embodiment will be described with reference to FIGS. 20 to 22. In the description of the deposition mask according to the fifth embodiment, the same or similar description as the deposition mask according to the first embodiment described above will be omitted.

Referring to FIG. 20, a plurality of through-holes are disposed in the deposition region DA. In detail, the effective region AA includes the first through-hole TH1. Also, the first non-effective region UA1 includes a second through-hole TH2. Also, the second non-effective region UA2 includes a third through-hole TH3.

The sizes or shapes of the first through-hole TH1, the second through-hole TH2, and the third through-hole TH3 may be the same as or similar to those of the first embodiment described above.

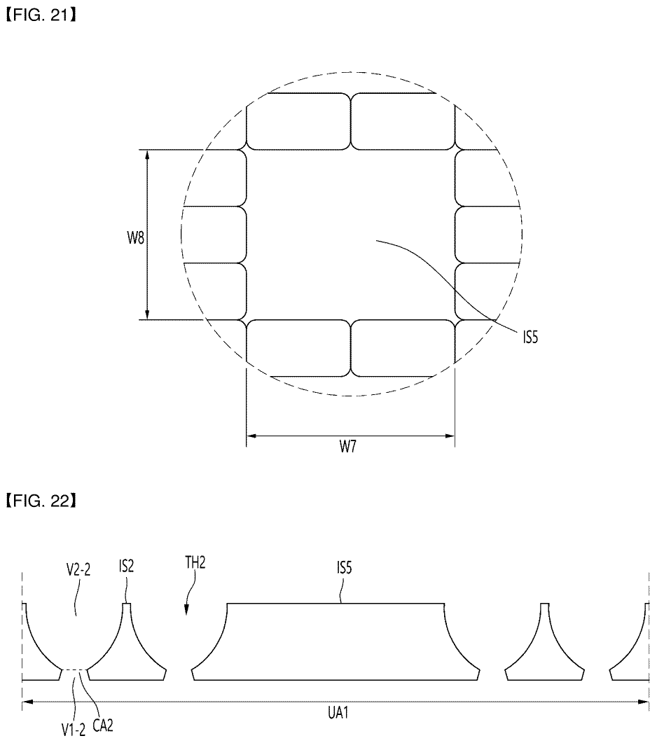

Referring to FIGS. 21 and 22, the deposition mask 100 includes a plurality of fifth island portions IS5.

The fifth island portion IS5 is disposed in the non-effective region. In detail, the fifth island portion IS5 is disposed in the first non-effective region UA1. Accordingly, the fifth island portion IS5 is spaced apart in the first direction 1D.

In the drawings, one fifth island portion IS5 is disposed in each first non-effective region UA1. However, the embodiment is not limited thereto. A plurality of fifth island portions IS5 may be disposed in each second non-effective region UA2.

The fifth island portion IS4 may have a different size or shape from the first island portion IS1, the second island portion IS2, and the third island portion IS3. For example, the first island portion IS1, the second island portion IS2, and the third island portion IS3 may have similar sizes or shapes. Also, the fifth island portion IS5 may have a different size or shape from the first island portion IS1, the second island portion IS2, and the third island portion IS3.

In detail, the shape of the fifth island portion IS5 is different from the shapes of the first island portion IS1, the second island portion IS2, and the third island portion IS3. Also, the area of the fifth island portion IS5 is larger than the areas of the first island portion IS1, the second island portion IS2, and the third island portion IS3.

The fifth island portion IS5 may have various shapes. For example, the fifth island portion IS5 may be formed in a shape having the same long width and short width. Alternatively, the fifth island portion IS5 may be formed in a shape having a long width and a short width different from each other.

The position of the effective region AA is aligned by the fifth island portion IS5. In detail, the intervals of the effective regions AA are aligned by the fifth island portion IS5. That is, the fifth island portion IS5 is a interval control mark. Accordingly, when the organic material is deposited on the deposition substrate by the deposition mask, the interval between the effective regions AA is made uniform by the fifth island portion IS5. Thus, the interval of the deposition patterns becomes uniform.

The fifth island portion IS5 may have a set size. For example, the fifth island portion IS5 includes a seventh width W7 and an eighth width W8. The seventh width W7 is a width in the first direction. The eighth width W8 is a width in the second direction.

The seventh width W7 may be 100 μm or less. In detail, the seventh width W7 may be 20 μm to 100 μm, 50 μm to 90 μm, or 60 μm to 80 μm. Also, the eighth width W8 may be 100 μm or less. In detail, the eighth width W8 may be 40 μm to 100 μm, 50 μm to 90 μm, or 60 μm to 80 μm. The seventh width W7 and the eighth width W8 may be the same. Alternatively, the seventh width W7 and the eighth width W8 may be different.

When the seventh and eighth widths W7 and W8 exceed 100 μm, an area that is not etched may increase in the first non-effective region UA1. Accordingly, the force applied by the tension becomes non-uniform by the first non-effective region UA1. Accordingly, deformation may occur in the deposition mask. Also, residual stress is concentrated in the fifth island portion. Accordingly, the waviness of the fifth island portion may be increased. Accordingly, the position and interval of the fifth island portion change. As a result, the interval of the effective regions also changes, thereby reducing the deposition quality.

Also, when the seventh width W7 and the eighth width W8 are less than 20 μm, the area of the fifth island portion becomes very small. Accordingly, when the interval between the effective regions is aligned by the fifth island portion, tolerance may increase. Accordingly, the tolerance of the interval of the effective regions is also increased, and thus the deposition quality is reduced.

The deposition mask according to the fifth embodiment includes the fifth island portion disposed in the non-effective region.

The area of the fifth island portion is larger than areas of the first island portion, the second island portion, and the third island portion.

Accordingly, intervals between the effective regions are aligned by the fifth island portion. Accordingly, the interval between the deposition patterns becomes uniform.

The characteristics, structures, effects, and the like described in the above-described embodiments are included in at least one embodiment of the present invention, but are not limited to only one embodiment. Furthermore, the characteristic, structure, and effect illustrated in each embodiment may be combined or modified for other embodiments by a person skilled in the art. Accordingly, it is to be understood that such combination and modification are included in the scope of the present invention.

In addition, embodiments are mostly described above, but the embodiments are merely examples and do not limit the present invention, and a person skilled in the art may appreciate that several variations and applications not presented above may be made without departing from the essential characteristic of embodiments. For example, each component specifically represented in the embodiments may be varied. In addition, it should be construed that differences related to such a variation and such an application are included in the scope of the present invention defined in the following claims.

1. A deposition mask comprising;
a metal plate including a deposition region and a non-deposition region,
wherein the metal plate has a first direction, which is a longitudinal direction, and a second direction, which is a width direction, defined,
wherein the metal plate includes a first surface and a second surface opposite to the first surface,
wherein the deposition region includes a plurality of effective regions; and a non-effective region,
wherein the non-effective region includes a first non-effective region between a plurality of effective regions; and a second non-effective region between the effective region and both ends of the metal plate in the second direction,
wherein a plurality of first through-holes are formed in the effective region,
wherein a plurality of second through-holes areformed in the first non-effective region,
wherein a plurality of third through-holes areformed in the second non-effective region,
wherein the second non-effective region includes an alignment region.
wherein the plurality of third through boles are provided around the alonment region in the second non-effective region, and
wherein a size of the alignment region is greater than a size of the third through hole.

2. The deposition mask of claim 1, wherein the first through-hole, the second through-hole, and the third through-hole have the same size.

3. The deposition mask of claim 1,
wherein the alignment region is defined as a region in which the metal plate is not etched,
wherein the metal plate includes at least one alignment pattern provided in the alignment region, and
wherein the alignment pattern is spaced from an edge of the alignment region.

4. The deposition mask of claim 3, wherein the second through-hole includes a small surface hole formed on the first surface and a large surface hole formed on the second surface,
wherein the third through-hole includes a small surface hole formed on the first surface and a large surface hole formed on the second surface,
wherein the alignment pattern includes small surface hole formed on the first surface and large surface hole formed on the second surface.

5. The deposition mask of claim 4, wherein a size of the large surface hole of the alignment pattern is the same as the size of the large surface hole of at least one of the second through-hole and the third through-hole.

6. The deposition mask of claim 4, wherein a size of the small surface hole of the alignment pattern is the same as the size of the small surface hole of at least one of the second through-hole and the third through-hole.

7. The deposition mask of claim 3, wherein the alignment region includes a first width defined as a width in a first direction and a second width defined as a width in a second direction,
wherein at least one of the first width and the second width is 1 mm to 5 mm.

8. The deposition mask of claim 3, wherein the alignment pattern includes a third width defined as a width in the first direction and a fourth width defined as a width in the second direction,
wherein the third width is 20 μm to 70 μm.

9. The deposition mask of claim 3, wherein the alignment region is multiple numbers faxing in the second direction with the effective region interposed therebetween.

10. A deposition mask comprising;
a metal plate including a deposition region and a non-deposition region,
wherein the metal plate has a first direction, which is a longitudinal direction, and a second direction, which is a width direction, defined,
wherein the deposition region includes a plurality of effective regions; and a non-effective region,
wherein the non-effective region includes a first non-effective region between a plurality of effective regions; and a second non-effective region between the effective region and both ends of the metal plate in the second direction,
wherein a plurality of first through-holes are formed in the effective region,
wherein a plurality of second through-holes are formed in the first non-effective region,
wherein a plurality of third through-holes and least one alignment pattern are formed in the second non-effective region,
wherein the non-effective region includes a first island portion provided between the plurality of third through holes, and a second island portion provided between the alignment pattern and the third through hole, and
wherein a size of the second island portion is different from a size of the first island portion.

11. The deposition mask of claim 10, wherein the size of the second island portion is greater than the size of the first island portion.
